(19) United States
(12) Patent Application Publication
(10) Pub. No.: US 2006/0270132 A1
(43) Pub. Date: Nov. 30, 2006

(54) Manufacturing process and structure of power junction field effect transistor

(75) Inventors: Jun Zeng, Taipei Hsien (TW); Po-I Sun, Taipei Hsien (TW)

Correspondence Address: MADSON & AUSTIN;GATEWAY TOWER WEST, SUITE 900, 15 WEST SOUTH TEMPLE, SALT LAKE CITY, UT, 84101, US

(73) Assignee: Pyramis Corporation

(21) Appl. No.: 11/194,847

(22) Filed: Aug. 1, 2005

(30) Foreign Application Priority Data
May 13, 2005 (TW) 094115672

(51) Int. Cl. H01L 21/337

(52) U.S. Cl. 438/186

(57) ABSTRACT

A manufacturing process and a power junction field-effect transistor (JFET) are provided. The basic concept of the present invention is to allow the current to flow vertically from the drain region on the bottom side to the source region on the topside of the device. By regulating the voltage applied between the gate regions and the source region, the power junction field-effect transistor (JFET) of the present invention can be built to handle large current and higher voltage for power management purposes, as is similar to the metal oxide semiconductor field effect transistor (MOSFET).

### FIELD OF THE INVENTION

The present invention relates to a manufacturing process and a structure of a power field-effect transistor, and more particularly to a manufacturing process and a structure of a power junction field-effect transistor.

### BACKGROUND OF THE INVENTION

Recently, field effect transistors (FETs) such as metal oxide semiconductor field effect transistors (MOSFETs) or junction field effect transistors (JFETs) have achieved a great deal of advance in their performance and manufacturing process technology. The field-effect transistor is a transistor that relies on an electric field to control the shape of the nonconductive depletion layer within a semiconductor material, thus controlling the conductivity of a channel in that material. In other words, once a voltage is applied between the gate region and the source region, the current is controlled to flow vertically from the drain region to the source region with the gate region in between. Like all transistors, field-effect transistors can be used as voltage-controlled variable resistors or voltage controlled current sources.

The junction field-effect transistor (JFET) uses voltage applied across a reverse-biased PN junction between the gate region and the source/drain region to control the width of the depletion region, which then controls the conductivity of a semiconductor channel. The metal oxide semiconductor field effect transistor (MOSFET) is a field-effect transistor having a metallic gate insulated from the channel by an oxide layer and the channel conductivity thereof is dependent only on the potential at the gate region.

The MOSFET device is extensively used in digital circuits because the structure thereof is developed toward minimization and it is a very efficient switch. As such, it is possible to fabricate a great number of MOS transistors in a single chip. The structure of the junction field-effect transistor (JFET) is distinguished from the metal oxide semiconductor field effect transistor (MOSFET). Due to the structure difference, the junction field-effect transistors (JFETs) are typically used as analog switches or signal amplifiers, especially low-noise amplifiers, but seldom used as logical operation units or power amplifiers.

Due to the specific structure, the conventional junction field-effect transistor (JFET) fails to handle large current for power management purposes. It is important to modify and regulate the structure and the manufacturing process of the junction field-effect transistor (JFET) so as to overcome the above-described disadvantages resulted from the prior art.

### SUMMARY OF THE INVENTION

The basic concept of the present invention is to allow the current to flow vertically from the drain region on the bottom side to the source region on the topside of the device. By regulating the voltage applied between the gate regions and the source region, the power junction field-effect transistor (JFET) of the present invention can be built to handle large current and higher voltage for power management purposes, as is similar to the metal oxide semiconductor field effect transistor (MOSFET).

In accordance with a first aspect of the present invention, there is provided a process for manufacturing a power junction field-effect transistor (JFET). The process comprising steps of (a) providing a substrate having an epitaxy layer formed thereon; (b) performing a first implanting procedure to implant a first dopant in the epitaxy layer, thereby forming a source layer on a surface of the epitaxy layer; (c) forming a first oxide layer on the source layer, and patterning the first oxide layer by a first photolithography and etching procedure to define a gate runner window, a gate window and a guard ring window therein; (d) etching the source layer and the epitaxy layer through the gate runner window, the gate window and the guard ring window, thereby defining a gate runner trench, a gate trench and a guard ring trench, respectively; (e) forming a sacrificial oxide layer on sidewalls and bottom surfaces of the gate runner trench, the gate trench and the guard ring trench; (f) performing a second implanting procedure to implant a second dopant in the epitaxy layer through the gate runner window, the gate window and the guard ring window, thereby forming a gate runner, a gate region and a guard ring region in the epitaxy layer underlying the gate runner trench, the gate trench and the guard ring trench, respectively; (g) completely removing the first oxide layer and the sacrificial oxide layer, and forming an inter-layer dielectrics layer on the source layer and in the gate runner trench, the gate trench and the guard ring trench; (h) patterning the inter-layer dielectrics layer by a second photolithography and etching procedure to define a gate runner/metal layer junction window and a source layer/metal layer junction window therein; and (i) depositing a metal layer on the resulting structure, and patterning the metal layer by a third photolithography and etching procedure to form a gate runner metal layer and a source metal layer, which are connected to the gate runner and the source layer, respectively.

In an embodiment, the substrate is an N+ silicon substrate, and the epitaxy layer is an N epitaxy layer.

In an embodiment, the first oxide layer is a field oxide layer.

In an embodiment, the first dopant is an N+ type of dopant.

In an embodiment, the process further comprises a step of performing an annealing procedure after the step (b).

In an embodiment, the first implanting procedure is a blanket implanting procedure.

In an embodiment, the second dopant is a P+ type of dopant.

In an embodiment, the process further comprises a step of performing an annealing procedure after the step (f).

Preferably, the inter-layer dielectrics layer is a deposition oxide layer.

In an embodiment, the area underlying the gate region is defined as a drain region.

In an embodiment, the process further comprises steps of (j) depositing a passivation layer on the gate runner metal layer and the source metal layer; and (k) patterning the passivation layer by a fourth photolithography and etching procedure to define first and second pad areas for the gate runner metal layer and the source metal layer, respectively.

Preferably, the passivation layer is made of silicon oxide or nitride oxide.

In accordance with a second aspect of the present invention, there is provided a structure of a power junction field-effect transistor (JFET). The structure of the power junction field-effect transistor (JFET) comprises a substrate; an epitaxy layer formed on the substrate, and comprising a gate trench and a gate runner trench therein; a gate region formed in the bottom of the gate trench of the epitaxy layer; a gate runner formed in the bottom of the gate runner trench of the epitaxy layer and electrically connected to the gate region; a source layer formed on the epitaxy layer; an inter-layer dielectrics layer formed on the source layer and filled in the gate runner trench and the gate trench, and comprising a gate runner/metal layer junction window and a source layer/metal layer junction window therein; and a gate runner metal layer and a source metal layer formed on the inter-layer dielectrics layer, and connected to the gate runner and the source layer through the gate runner/metal layer junction window and the source layer/metal layer junction window, respectively.

The above contents of the present invention will become more readily apparent to those ordinarily skilled in the art after reviewing the following detailed description and accompanying drawings, in which:

### BRIEF DESCRIPTION OF THE DRAWINGS

FIGS. 1(a)˜1(j) illustrate the steps of a process for manufacturing a power junction field-effect transistor (JFET) according to a preferred embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

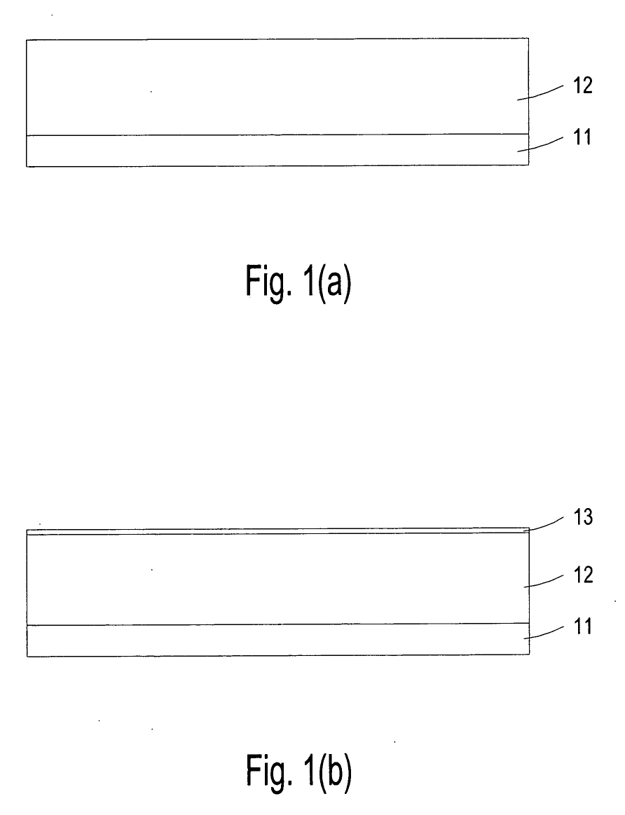

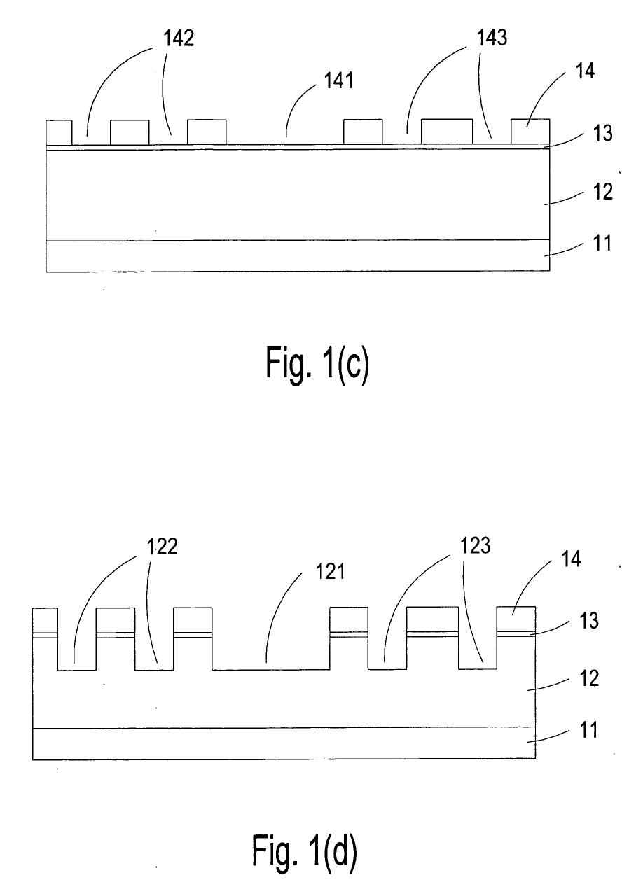

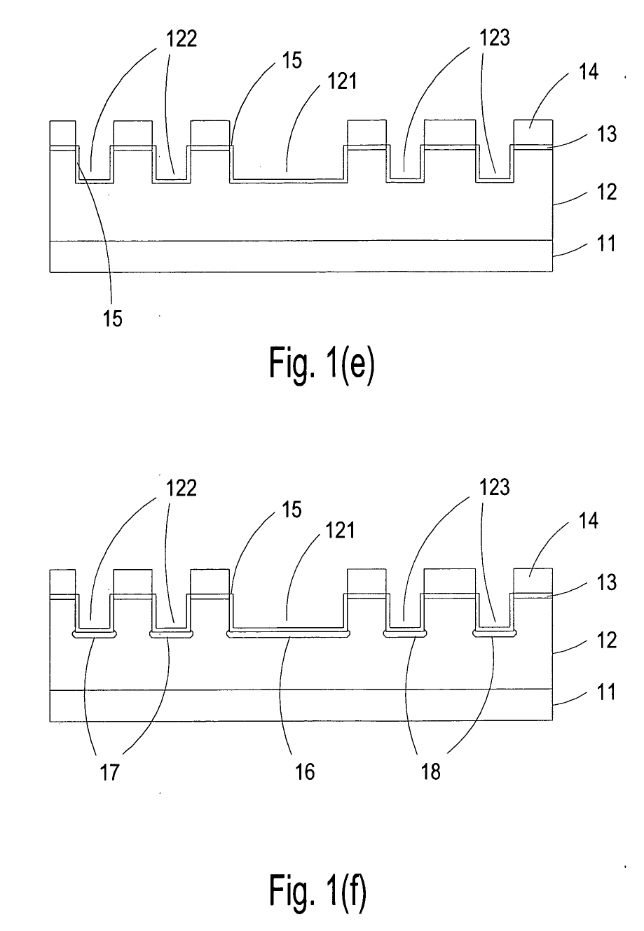

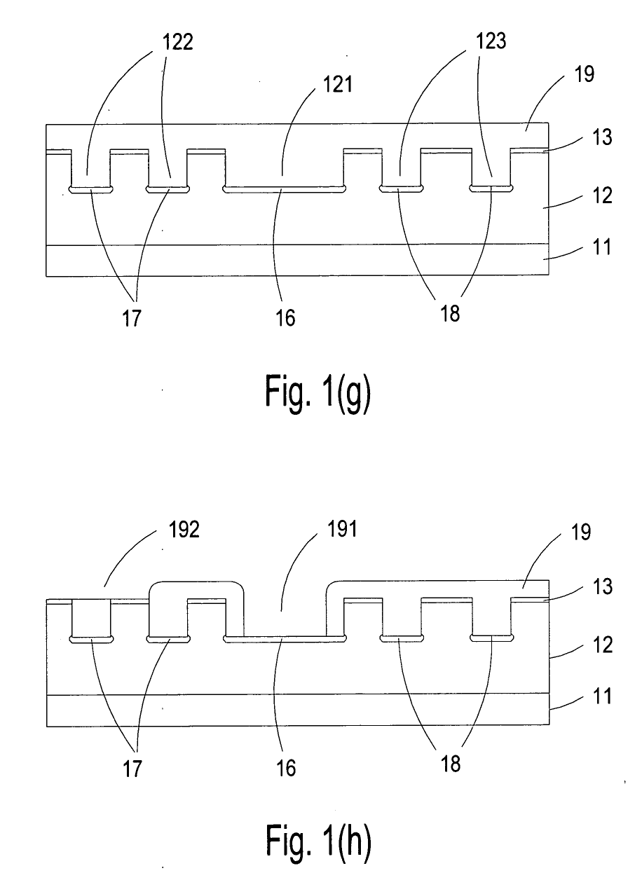

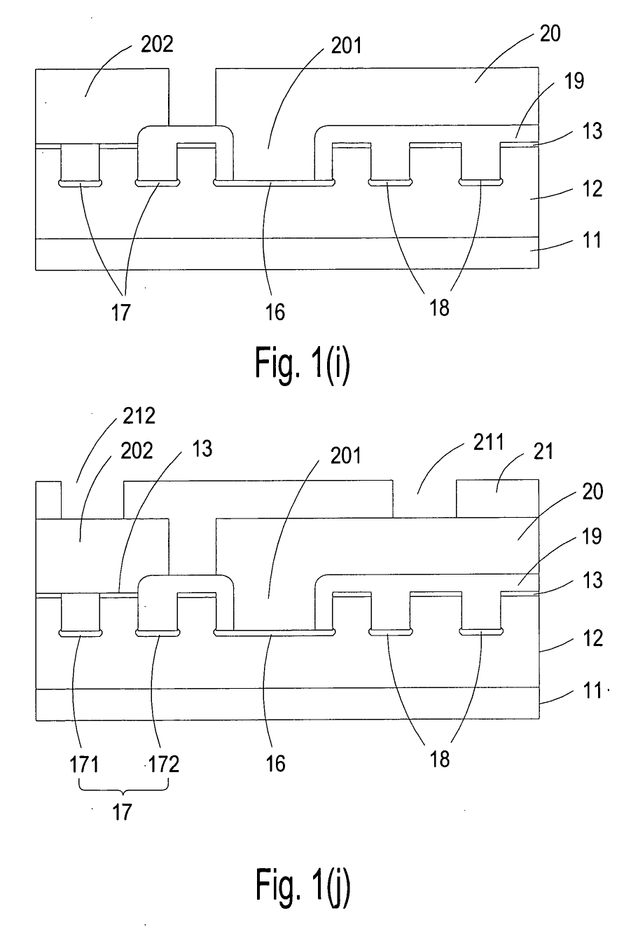

A process for manufacturing a power junction field-effect transistor (JFET) according to a preferred embodiment of the present invention will be illustrated as follows with reference to FIGS. 1(a)˜1(j).

Firstly, as shown in FIG. 1(a), a substrate 11 such as an N+ silicon substrate is provided, and an epitaxy layer 12 such as an N epitaxy layer is then formed on the substrate 11. Then, a first implanting procedure such as a blanket implanting procedure is performed to implant a first dopant in the epitaxy layer 12, thereby forming a source layer 13 on the surface of the epitaxy layer 12, as shown in FIG. 1(b). In some embodiments, the first dopant is an N+ dopant, and thus the source layer 13 is N+ doped. After the first implanting procedure, an annealing procedure is performed to drive-in the N+ source layer 13.

Next, a first oxide layer 14 such as a filed oxide layer is formed on the source layer 13 according to a thermal oxidation procedure. Then, the first oxide layer 14 is patterned by a first photolithography and etching procedure to define a gate runner window 141, a gate window 142 and a guard ring window 143, as shown in FIG. 1(c).

Next, the source layer 13 and the epitaxy layer 12 are etched through the gate runner window 141, the gate window 142 and the guard ring window 143, thereby defining a gate runner trench 121, a gate trench 122 and a guard ring trench 123, as shown in FIG. 1(d). Then, as shown in FIG. 1(e), by a thermal oxidation procedure, a sacrificial oxide layer 15 is formed on sidewalls and bottom surfaces of the gate runner trench 121, the gate trench 122 and the guard ring trench 123. Then, a second implanting procedure is performed to implant a second dopant in the epitaxy layer 12 through the gate runner window 141, the gate window 142 and the guard ring window 143 to form a gate runner 16, a gate region 17 and a guard ring region 18 in the epitaxy layer 12 underlying the gate runner trench 121, the gate trench 122 and the guard ring trench 123, respectively. The gate runner 16 is electrically connected to the gate region 17. In some embodiments, the second dopant is a P+ dopant, and thus the gate runner 16, the gate region 17 and the guard ring region 18 are P+ doped. After the second implanting procedure, another annealing procedure is performed to drive-in the P+ gate runner 16, the P+ gate region 17 and the P+ guard ring region 18 to form the resulting structure of FIG. 1(f).

Next, the first oxide layer 14 and the sacrificial oxide layer 15 are completely removed, and then an ILD (Inter-Layer Dielectrics) layer 19 such as a deposition oxide layer is deposited on the source layer 13 and filled in the gate runner trench 121, the gate trench 122 and the guard ring trench 123, thereby forming the resulting structure of FIG. 1(g). Then, the ILD layer 19 is patterned by a second photolithography and etching procedure to form a gate runner/metal layer junction window 191 and a source layer/metal layer junction window 192, as shown in FIG. 1(h).

Next, a metal layer 20 is deposited on the resulting structure. Then, as shown in FIG. 1(i), the metal layer 20 is patterned by a third photolithography and etching procedure to form a gate runner metal layer 201 and a source metal layer 202, which are connected to the gate runner 16 and the source layer 13, respectively. Afterwards, a passivation layer 21 is deposited on the resulting structure of 1(i). The passivation layer 21 is then patterned by a fourth photolithography and etching procedure to define a pad area 211 for the gate runner metal layer 201 and another pad area 212 for the source metal layer 202. Meanwhile, the power junction field-effect transistor of the present invention as shown in FIG. 1(j) is produced accordingly.

Please refer again to FIG. 1(j), the structure of the power junction field-effect transistor (JFET) comprises a substrate 11; an epitaxy layer 12 formed on the substrate 11 and comprising a gate runner trench 121, a gate trench 122 and a guard ring trench 123 defined therein (as shown in FIG. 1(d)); a pair of gate regions 17 comprising two gate units 171 and 172 parallel with each other and formed in the bottom of the gate trench 122 of the epitaxy layer 12; a gate runner 16 formed in the bottom of the gate runner trench 121 of the epitaxy layer 12 and electrically connected to the gate regions 17; a source layer 13 formed on the surface of the epitaxy layer 12; an inter-layer dielectrics layer 19 formed on the source layer 13, filling in the gate runner trench 121, the gate trench 122 and the guard ring trench 123 and having a gate runner/metal layer junction window 191 and a source layer/metal layer junction window 192 therein (as shown in FIG. 1(h)); and a gate runner metal layer 201 and a source metal layer 202 formed on the inter-layer dielectrics layer 19 and connected to the gate runner 16 and the source layer 13 through the gate runner/metal layer junction window 191 and the source layer/metal layer junction window 192, respectively.

In some embodiments, the substrate 11 is an N+ silicon substrate, and the epitaxy layer 12 is an N epitaxy layer. In addition, the gate regions 17 and the gate runner 16 are P+ doped. Whereas, the source layer 13 is N+ doped.

In the above embodiments, the area underlying the gate regions 17 is defined as a drain region. By regulating the voltage applied between the gate regions 17 and the source layer 13, the current would flow vertically from the drain region on the bottom side to the source layer 13 on the topside of the device through the gate units 171 and 172. Therefore, the power junction field-effect transistor (JFET) of the present invention can be built to handle large current and higher voltage for power management purposes, as is similar to the metal oxide semiconductor field effect transistor (MOSFET).

By the way, the power junction field-effect transistor (JFET) of the present invention further comprises a guard ring region 18 formed in the bottom of the guard ring trench 123 of the epitaxy layer 12. The guard ring region 18 is preferably P+ doped. The power junction field-effect transistor (JFET) further comprises a passivation layer 21 formed on the gate runner metal layer 201 and the source metal layer 202. The passivation layer 21 is etched to define a pad area 211 for the gate runner metal layer 201 and another pad area 212 for the source metal layer 202 so as to implement wire bonding operations through the pad areas 211 and 212, respectively. Preferably, the passivation layer 21 is made of silicon oxide or nitride oxide.

It is noted that, however, those skilled in the art will readily observe that numerous modifications and alterations of the structure and the manufacturing process may be made while retaining the teachings of the invention. For example, a great number of identical and paralleled JFET units may be included in a semiconductor chip to handle larger current. Accordingly, the above disclosure should be limited only by the bounds of the following claims.

From the above description, the power junction field-effect transistor (JFET) of the present invention can be built to handle large current and higher voltage for power management purposes by regulating the voltage applied between the gate regions and the source layer. As a consequence, the purpose for implementing power management is similar to the metal oxide semiconductor field effect transistor (MOSFET) by using the power junction field-effect transistor (JFET) of the present invention.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A process for manufacturing a power junction field-effect transistor (JFET), comprising steps of:
(a) providing a substrate having an epitaxy layer formed thereon;
(b) performing a first implanting procedure to implant a first dopant in said epitaxy layer, thereby forming a source layer on a surface of said epitaxy layer;
(c) forming a first oxide layer on said source layer, and patterning said first oxide layer by a first photolithography and etching procedure to define a gate runner window, a gate window and a guard ring window therein;
(d) etching said source layer and said epitaxy layer through said gate runner window, said gate window and said guard ring window, thereby defining a gate runner trench, a gate trench and a guard ring trench, respectively;
(e) forming a sacrificial oxide layer on sidewalls and bottom surfaces of said gate runner trench, said gate trench and said guard ring trench;
(f) performing a second implanting procedure to implant a second dopant in said epitaxy layer through said gate runner window, said gate window and said guard ring window, thereby forming a gate runner, a gate region and a guard ring region in said epitaxy layer underlying said gate runner trench, said gate trench and said guard ring trench, respectively;
(g) completely removing said first oxide layer and said sacrificial oxide layer, and forming an inter-layer dielectrics layer on said source layer and in said gate runner trench, said gate trench and said guard ring trench;
(h) patterning said inter-layer dielectrics layer by a second photolithography and etching procedure to define a gate runner/metal layer junction window and a source layer/metal layer junction window therein; and
(i) depositing a metal layer on the resulting structure, and patterning said metal layer by a third photolithography and etching procedure to form a gate runner metal layer and a source metal layer, which are connected to said gate runner and said source layer, respectively.

2. The process according to claim 1 wherein said substrate is an N+ silicon substrate, and said epitaxy layer is an N epitaxy layer.

3. The process according to claim 1 wherein said first oxide layer is a field oxide layer.

4. The process according to claim 1 wherein said first dopant is an N+ type of dopant.

5. The process according to claim 1 further comprising a step of performing an annealing procedure after said step (b).

6. The process according to claim 1 wherein said first implanting procedure is a blanket implanting procedure.

7. The process according to claim 1 wherein said second dopant is a P+ type of dopant.

8. The process according to claim 1 further comprising a step of performing an annealing procedure after said step (f).

9. The process according to claim 1 wherein said inter-layer dielectrics layer is a deposition oxide layer.

10. The process according to claim 1 wherein the area underlying said gate region is defined as a drain region.

11. The process according to claim 1 further comprising steps of:
(j) depositing a passivation layer on said gate runner metal layer and said source metal layer; and
(k) patterning said passivation layer by a fourth photolithography and etching procedure to define first and second pad areas for said gate runner metal layer and said source metal layer, respectively.

12. The process according to claim 11 wherein said passivation layer is made of silicon oxide or nitride oxide.

13. A structure of a power junction field-effect transistor (JFET), comprising:
a substrate;
an epitaxy layer formed on said substrate, and comprising a gate trench and a gate runner trench therein;
a gate region formed in the bottom of said gate trench of said epitaxy layer;
a gate runner formed in the bottom of said gate runner trench of said epitaxy layer and electrically connected to said gate region;
a source layer formed on said epitaxy layer;
an inter-layer dielectrics layer formed on said source layer and filled in said gate runner trench and said gate trench, and comprising a gate runner/metal layer junction window and a source layer/metal layer junction window therein; and
a gate runner metal layer and a source metal layer formed on said inter-layer dielectrics layer, and connected to said gate runner and said source layer through said gate runner/metal layer junction window and said source layer/metal layer junction window, respectively.

14. The structure according to claim 13 wherein said substrate is an N+ silicon substrate, and said epitaxy layer is an N epitaxy layer.

15. The structure according to claim 13 wherein said gate region is doped with a P+ dopant, and said source layer is doped with an N+ dopant.

16. The structure according to claim 13 wherein said inter-layer dielectrics layer is a deposition oxide layer.

17. The structure according to claim 13 further comprising a drain region underlying said gate regions.

18. The structure according to claim 13 further comprising a P+ guard ring formed in said epitaxy layer.

19. The structure according to claim 13 further comprising a passivation layer formed on said gate runner metal layer and said source metal layer and having first and second pad areas defined therein.

20. The structure according to claim 13 wherein said gate region includes two gate units parallel with each other and formed in said epitaxy layer.
